(19) United States
(12) Patent Application Publication
(10) Pub. No.: US 2004/0144971 A1
(43) Pub. Date: Jul. 29, 2004

(54) Optoelectronic component with a pulse generating device

(76) Inventor: Bernhard Stegmuller, Augsburg (DE)

Correspondence Address: ESCHWEILER & ASSOCIATES, LLC, NATIONAL CITY BANK BUILDING, 629 EUCLID AVE., SUITE 1210, CLEVELAND, OH, 44114, US

(21) Appl. No.: 10/735,465

(22) Filed: Dec. 12, 2003

(30) Foreign Application Priority Data
Dec. 16, 2002 (DE) 102 60 378.2

(51) Int. Cl. H01L 29/06

(52) U.S. Cl. 257/17

(57) ABSTRACT

The invention relates to an optoelectronic component with a pulse generating device for generating light pulses. The component includes an absorber device that borders against a silvered edge thereof, and includes an amplifier device that is arranged on the side of the absorber device facing away from the silvered edge. The component further includes an active layer applied on a semiconductor substrate of the component that is associated with the amplifier device. In order that the light pulses have a high contrast or a high extinction ratio, a further active layer is provided on the semiconductor substrate that is associated with the absorber device.

### REFERENCE TO RELATED APPLICATIONS

This application claims the benefit of the priority date of German application DE 102 60 378.2, filed on Dec. 16, 2002, the contents of which are herein incorporated by reference in their entirety.

### FIELD OF THE INVENTION

The invention relates to an optical component with a pulse generating device.

### BACKGROUND OF THE INVENTION

An optoelectronic component is described in the publication “Mode-Locking at Very High Repetition Rates More than Terahertz in Passively Mode-Locked Distributed-Bragg-Reflector Laser Diodes” (Shin Arahira, Yasuhiro Matsui, Yoh, Ogawa, IEEE JOURNAL OF QUANTUM ELECTRONICS, VOL. 32, No. 7, JULY 1996). The already known optoelectronic component has an absorber device, which is 75 μm long and is arranged on one edge of the optoelectronic component. This edge of the optoelectronic component is silvered with a layer of aluminum dioxide and gold. Next to the absorber device, in fact bordering it, lies an amplifier device with a length of 750 μm. Between a light emission surface of the component lying opposite the silvered edge of the optoelectronic component and the amplifier device there are further electro-optical components, namely a phase monitoring device with a length of 150 μm and a DBR device with a length of 90 μm.

With regard to its internal construction, the already known optoelectronic component is an n-doped indium phosphite substrate, on which an MQW (Multiple Quantum Well) layer is deposited as an active layer. This active MQW layer is associated with the amplifier device and the absorber device. A p-doped indium phosphite (p-InP) layer, to which are connected a contact layer and a contact metallization, is applied on the active MQW layer. With the already known optical component, the silvered edge and the DBR grating each form a “resonator wall” of an optical resonator; the absorber device and the amplifier device are arranged within this resonator.

### SUMMARY OF THE INVENTION

The invention is based on the object of specifying an optoelectronic component for producing short light pulses at a high repetition rate, in which the light pulses have a high contrast or a high extinction ratio.

Hence, according to the invention, a further active layer is provided, which is associated with the absorber device and is applied on the semiconductor substrate. The further active layer can at the same time be arranged above or below the one active layer.

An important advantage of the optoelectronic component according to the invention can be seen in that a further active layer (or a further active layer packet) is present in addition to the one active layer (or to the one active layer packet). Hence, in particular, it is possible to optimize the one active layer, especially with regard to its amplifier characteristics, for the amplifier device and the further active layer especially for the absorber device. Due to the separate optimization of the absorber device and the amplifier device, a particularly high contrast or a high extinction ratio of light pulses can be obtained.

This will now be briefly explained: A pulse mode of the optoelectronic component assumes, on the one hand, that the dependency Av of the gain V on the carrier density N is very small compared with the dependency Aa of the absorption A on the carrier density N; therefore:

Av=δV/δN<<Aa=δA/δN

On the other hand, with regard to a high contrast or a high extinction ratio of the light pulses, it is also necessary that there is strong saturation of the optical gain in the amplifier device. Both criteria can be very well fulfilled with the optoelectronic component according to the invention, namely because the band gaps of the two active layers, for example, can each be adjusted separately.

A further important advantage of the optical component according to the invention can be seen in that, due to the two active layers, more freedom is achieved with respect to the geometrical dimensioning and setting of the working parameters, such as the current in the amplifier device and the voltage in the absorber device.

According to one advantageous embodiment of the invention, one resonator wall of the optical resonator is formed by a silvered edge of the component. Advantageously, in one example the absorber device borders directly onto the silvered edge of the component.

According to a further advantageous embodiment of the invention, at least one of the two active layers is a QD (Quantum Dot) or an MQD (Multiple Quantum Dot) layer. In particular, the first criterion, according to which the dependency Av of the gain V on the carrier density N should be very much greater than that of the absorption, can then be particularly well and thus advantageously fulfilled.

By the provision of a QD layer or an MQD layer in the active layer associated with the amplifier device, advantageously very high pulse repetition frequencies can be achieved even with relatively high pulse powers, as namely the “recovery” of the gain with QD layers takes place considerably faster than with QW (Quantum Well) layers. Here, “recovery” of the gain is understood to mean that the charge carrier densities required for producing light pulses can be re-formed or generated relatively quickly, once the charge carrier density in the case of a previously generated light pulse has been reduced to a great extent.

With regard to a particularly easy and cost-effective manufacture of the optoelectronic component, it is seen as advantageous if the light emission surface, instead of being provided with an antireflective layer, is provided with a weakly reflective coating in its place. Here, a weakly reflective layer is understood to mean a layer, the degree of reflection of which is less than the degree of reflection of the silvered edge of the component. In this way, the weakly reflective coating can also form a resonator wall of the resonator. Furthermore, this advantageous embodiment of the optoelectronic component also differs quite considerably from other optoelectronic components in which laser diodes and electroabsorption modulators are combined with one another; for with such “combinations” with laser diodes and electroabsorption modulators, very good antireflective decoupling end surface or light emission surface is generally always available.

In order to ensure that the light pulses generated by the absorber device and the amplifier device achieve the required output power at the light emission surface of the optoelectronic component, it is seen as advantageous if the pulse generating device has a further amplifier device, which is arranged next to the one amplifier device, namely on the side opposite the absorber device.

For decoupling the two amplifier devices, it is seen as advantageous if an isolating device, in particular a Bragg grating, is arranged between the one amplifier device and the further amplifier device. In this case, the isolating device can advantageously also form a resonator wall of the resonator.

In order at the same time to achieve strong electrical and optical decoupling between the two amplifier devices in the longitudinal direction—i.e. in the direction of the light beam produced by the optoelectronic component—it is seen as advantageous if the isolating device extends into the two active layers.

Advantageously, at least one further pulse generating device, which is located between the light emission surface of the optoelectronic component and the one pulse generating device, can be present in the optoelectronic component. At the same time, each of the further pulse generating devices should advantageously include at least one auxiliary amplifier device and at least one auxiliary absorber device.

For decoupling the pulse generating devices, it is seen as advantageous if at least one isolating element is provided between the one pulse generating device and the at least one further auxiliary pulse generating device.

Such an isolating element can advantageously be formed by a recess, a trench formed by ion implantation and/or by a grating structure.

Furthermore, it is seen as advantageous if the electrical connector pads for the electrical control of the optoelectronic component are tapered, at least in as far as the connector pads of the absorber device are concerned. A tapered design of the electrical connector pads namely has the advantage that these guarantee a particularly good transmission characteristic, even for very high electrical frequencies.

With regard to the absorber device, it is seen as advantageous if a blocking voltage is applied to this in order to guarantee that the charge carrier pairs generated in the further active layer are dissipated as quickly as possible.

In order to achieve a situation where the light pulses produced by the optoelectronic component are as free from jitter as possible, it is seen as advantageous if a modulated blocking voltage is applied to the absorber device. When the blocking voltage is modulated, triggering of the light pulses can be achieved by the modulated blocking voltage, resulting in a particularly low-jitter behavior of the light pulses.

In the case of the absorber device, this can advantageously be an electroabsorption modulator (EAM). In addition, the invention is based on the object of specifying a method for producing optical light pulses, in which a particularly high contrast or a particularly high extinction ratio of the pulse sequences is achieved.

According to the invention, this problem is solved by a method in which an optoelectronic component according to the invention is used and a modulated blocking voltage is applied to the absorption device.

An important advantage of the method according to the invention can be seen in that the light pulses are triggered by applying a modulated blocking voltage so that the light pulses produced have very low jitter.

A particularly low-jitter behavior of the light pulses can then advantageously be achieved if the modulation frequency of the blocking voltage is adjusted in such a way that the pulse repetition rate of the light pulses is an integer multiple of the modulation frequency. Specifically, if, the modulation frequency is chosen appropriately, this results in “locking-in” of the light pulse generation relative to the electrical modulation signal.

At the same time, reliable “locking-in” of the optical light pulses is advantageously achieved if the integer multiple is chosen to be less than one hundred, in particular less than eleven.

### BRIEF DESCRIPTION OF THE DRAWINGS

For the explanation of the invention:

FIG. 1 shows an exemplary embodiment of an optoelectronic component according to the invention,

FIG. 2 shows a second exemplary embodiment of an optoelectronic component according to the invention,

FIG. 3 shows a plan view of the exemplary embodiment as shown in FIG. 2,

FIG. 4 shows a third exemplary embodiment of an optoelectronic component according to the invention, and

FIG. 5 shows a fourth exemplary embodiment of an optoelectronic component according to the invention.

### DETAILED DESCRIPTION OF THE INVENTION

In the figures, identical or comparable components are regularly identified with the same reference symbols.

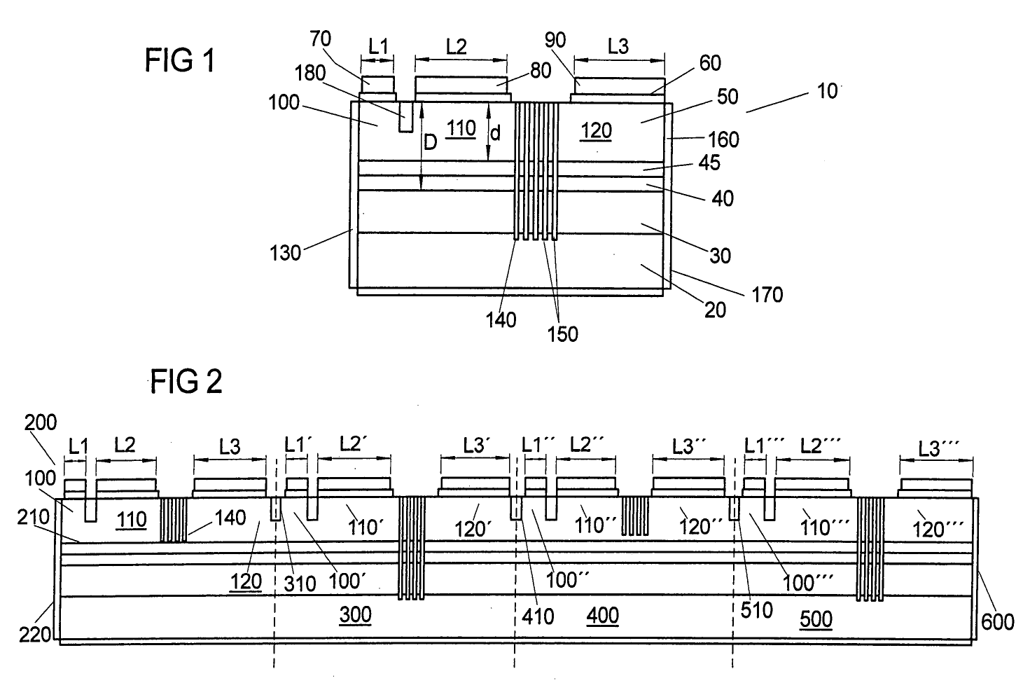

An optoelectronic component 10 with a semiconductor substrate 20 can be seen in FIG. 1. The semiconductor substrate 20 can be an n-doped material from the III-V material system. Indium phosphite or gallium arsenide is of particular interest for the material.

An active layer 30 and a further active layer 40 are applied to the substrate 20—for example, by a deposition method. On the further active layer 40 there is an intermediate layer 45 and a cover layer 50, which is provided with a highly doped contact layer 60.

As can be seen from FIG. 1, the contact layer 60 is structured, for example, by means of an etching step. A first contact 70, a second contact 80 and a third contact 90 are located on the structured contact layer 60.

The optoelectronic component 10 has three components, namely an absorber device 100, an amplifier device 110 and a further amplifier device 120. The absorber device 100 can advantageously be an electroabsorption modulator (EAM).

In this case, the absorber device 100 is located directly on a silvered edge 130 of the optoelectronic component 10 and makes contact with the first contact 70. The edge 130 is provided with a very strongly reflective layer, which can, for example, be a metal layer.

The amplifier device 110, which makes contact with the second contact 80 is located next to the absorber device 100, namely on the side facing away from the edge 130. The one amplifier device 110—on the side opposite the edge 130—is connected to an isolating device 140, which may, for example, be a Bragg structure or a Bragg grating. In the exemplary embodiment as shown in FIG. 1, the isolating device 140 is formed by vertically running layers 150, none of which exceeds a thickness of 1 μm and which altogether form a layer packet with a width between 2 μm and 50 μm.

The silvered edge 130 and the isolating device 140 thus form resonator walls of a resonator, in which the absorber device 100 and the amplifier device 110 are arranged.

The further amplifier device 120, which can be controlled by means of the third contact 90 is located on the side of the isolating device 140 facing away from the amplifier device 110. The further amplifier device 120 is bounded on its side facing away from the isolating device 140 by a light emission surface 160.

The light emission surface 160 is silvered with a weakly reflective coating 170, which may, for example, be an oxide or nitride layer.

The length L1 of the absorber device 100 is advantageously 2 to 100 μm. The amplifier device 110 has a length L2, which may be between 50 and 500 μm. The further amplifier device 120 has a length L3 between 50 and 500 μm.

As can also be seen from FIG. 1, the absorber device 100 and the amplifier device 110 are separated by a separating point 180. The separating point 180 can be formed by a recess or a trench produced by ion implantation. The width of the separating point 180 should advantageously not exceed 10 μm.

With regard to the layer sequence of the optoelectronic component 10, it is seen as advantageous if the thickness d of the cover layer 50 does not exceed a value of 3 μm. The whole layer packet comprising the cover layer 50 and the one active layer 30 and the further active layer 40, in one example, should not exceed a thickness D of 5 μm overall.

The one active layer 30 is optimized for the amplifier device 110 and has a multiple quantum well layer (MQW layer) or a quantum dot or multiple quantum dot layer. The layer thickness of the active layer 30, in one example, is advantageously in the order of magnitude between 200 and 400 nm. The layer composition of quantum dot layers is known per se and described, for example, in the article “Ultrafast Gain Recovery and Modulation Limitations in Self-Assembled Quantum-Dot Devices” (T. W. Berg, S. Bischoff, I. Magnusdottir, J. Mork, IEEE PHOTONICS TECHNOLOGY LETTERS, VOL. 13, NO. 6, JUNE 2001, Pages 541 ff.), which is hereby incorporated by reference in its entirety.

The further active layer 40 is a layer which is especially optimized for the absorber device 100. This further active layer 40 can be an MQW layer or a QD layer or an MQD layer and can advantageously have a thickness of 50 nm to 100 nm.

With regard to the layer thicknesses of the two active layers 30 and 40, for completeness it should be noted that the ratio of the layer thicknesses of the two layers to one another does not play a major role in itself; what is important is that the one layer 30 is optimized especially for the amplifier device 110 and the further active layer 40 is optimized especially for the absorber device 100.

The optimization of the two active layers 30 and 40 is carried out primarily with regard to the band gap. The one active layer 30 therefore has a band gap which is especially suitable for the amplifier device 110 and thus for amplifier operation. The further active layer 40 is optimized so that the absorber device 100 works well. By appropriate selection of the band gaps, it is possible for the dependency Av of the gain V of the amplifier device 110 on the carrier density N to be very small compared to the dependency Aa of the absorption A of the absorber device 100 on the carrier density N. Then:

Av=δV/δN<<Aa=δA/δN.

Furthermore, strong saturation of the optical gain in the amplifier device 110 can be achieved.

The one active layer 30 and the further active layer 40, in one exemplary aspect of the invention, should advantageously have band gaps such that the following two conditions are fulfilled:

1^{st} condition:

Et(further active layer 40=“absorber layer”)≈hυ

2^{nd} condition:

Et(active layer 30=“amplifier layer”)−Et(further active layer 40=“absorber layer”)≦30 meV

Here, h designates Planck's constant, υ the optical frequency of the light pulses, Et (active layer 30=“amplifier layer”) the band gap for the radiating transition for the active layer 30, and Et (further active layer 40=“absorber layer”) the band gap for the radiating transition for the further active layer 40.

It is particularly advisable if the difference in the band gaps is less than 10 to 15 meV, when therefore:

Et(active layer 30=“amplifier layer”)−Et(further active layer 40=“absorber layer”)≦15 meV

In summary, the component 10 has a light pulse generating device 190, i.e. a device which can or is intended to generate light pulses. The value of the gain of the amplifier device 110 must be suitably chosen for this. At the same time, with the optoelectronic component 10 as shown in FIG. 1, it is also possible that the gain V of the amplifier device 110 reaches a value of only

V=1 and the amplifier device 110 thus works only as an “optical phase shifter”. In such a mode of operation of the amplifier device 110, the further amplifier device 120 is used to achieve the required output power of the light pulses.

A further exemplary embodiment of an optoelectronic component according to the invention is shown in cross section in FIG. 2. The optoelectronic component as shown in FIG. 2 carries the reference symbol 200 and has a pulse generating device 210. In its construction, the pulse generating device 210 corresponds extensively to the pulse generating device 190 of the optoelectronic component 10 as shown in FIG. 1. The pulse generating device 210 thus has the absorber device 100, the amplifier device 110, the isolating device 140 and the further amplifier device 120. These components 100, 110, 140 and 120 have already been explained above in connection with the exemplary embodiment as shown in FIG. 1. With the optoelectronic component 200 as shown in FIG. 2, the pulse generating device 210 is arranged in such a way that the absorber device 100 borders directly on the silvered edge 220 of the component 200.

Furthermore, the isolating device 140 as shown in FIG. 2 is designed slightly differently from the exemplary embodiment as shown in FIG. 1; hence, the vertically running layers 150 do not go through the two active layers 30 and 40 but penetrate only the cover layer 50.

Connected to the pulse generating device 210 on the side opposite the silvered edge 220 is a first auxiliary pulse generating device 300, which is separated from the pulse generating device 210 by a separating point 310. The separating point 310 can be a recess or a trench produced by ion implantation, the width of which should preferably not exceed 10 μm and the depth of which should preferably not exceed 2 μm. Otherwise, the construction of the first auxiliary pulse device 300 corresponds in principle to the construction of the pulse generating device 190 as shown in FIG. 1.

Explicitly, the first auxiliary pulse generating device 300 has an auxiliary absorber device 100′, an auxiliary amplifier device 110′ and a further auxiliary amplifier device 120′. Here, the length of the auxiliary absorber device 100′ is shown in FIG. 1 with the reference symbol L1′. The length of the auxiliary amplifier device 110′ carries the reference symbol L2′ and the length of the further auxiliary amplifier device 120′ carries the reference symbol L3′.

In the case of the first auxiliary pulse generating device 300, the lengths L1′, L2′ and L3′ are optimized in themselves and do not have to have a specified relationship or reference symbol to the corresponding dimensions of the pulse generating device 210.

Connected to the first auxiliary pulse generating device 300 is a second auxiliary pulse generating device 400, which is separated from the first auxiliary pulse generating device 300 by a further separating point 410. With regard to its construction, the second auxiliary pulse generating device 400 can correspond to the pulse generating device 210. This means that the second auxiliary pulse generating device 400 can likewise have an auxiliary absorber device 100″, an auxiliary amplifier device 110″ and a further auxiliary amplifier device 120″. The lengths of the devices 100″, 110″ and 120″ are identified in FIG. 2 by the reference symbols L1″, L2″ and L3″.

Connected to the second auxiliary pulse generating device 400 on the side facing away from the first auxiliary pulse generating device 300 is a third auxiliary pulse generating device 500. In turn, this third auxiliary pulse generating device 500 is equipped with an auxiliary absorber device 100′″, an auxiliary amplifier device 110′″ and a further auxiliary amplifier device 120′″. The lengths of the three components are identified in FIG. 2 by the reference symbols L1′″, L2′″ and L3′″.

A separating point 510 is present in the cover layer 50 between the third auxiliary pulse generating device 500 and the second auxiliary pulse generating device 400.

On its side facing away from the second auxiliary pulse generating device 400, the third auxiliary pulse generating device 500 is provided with a weakly reflective coating 600, which, at the same time, forms the light emission surface of the optoelectronic component 200.

The optoelectronic component as shown in FIG. 2 can be sized in such a way that all four pulse generating devices 210, 300, 400 and 500 each generate their own light pulses with their own repetition rate. Instead of this, however, it is also possible to adjust the coupling between the individual pulse generating devices in such a way that the optoelectronic component 200 as shown in FIG. 1 generates light pulses, which are at only a single pulse frequency or repetition frequency. Preferably, the optoelectronic component 200 can then be sized so that the shortest resonator length of the four pulse generating devices determines the pulse repetition frequency.

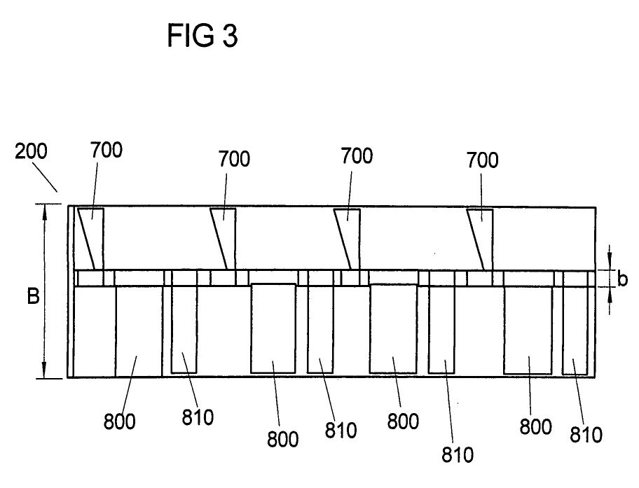

A plan view of the optoelectronic component 200 as shown in FIG. 2 is shown in FIG. 3. Connector pads 700 for the electrical connection of the absorber devices 100, 100′, 100″ and 100′″ can be seen. Furthermore, connector pads 800 are provided for the connection of the amplifier devices 110, 110′, 110″ and 110′″ as well as further connector pads 810 for the electrical connection of the further amplifier devices 120, 120′, 120″ and 120′″.

It can be seen from FIG. 3 that the electrical connector pads 700 for the absorber devices have a tapered design. A particularly good electrical transmission characteristic can be achieved by tapering the electrical connector pads 700. An electrical blocking voltage, the electrical pulse repetition frequency of which can be 10 GHz or more, can thus be applied to the absorber devices, for example. Triggering of the light pulses can be achieved by applying a modulated blocking voltage to the absorber devices.

At the same time, the modulation frequency of the blocking voltage for the electrical control of the absorber devices should be chosen so that the pulse rate of the optical light pulses is an integer multiple of the electrical modulation frequency of the blocking voltage. A particularly good trigger characteristic can then be achieved if the pulse rate of the light pulses is a multiple of about 10 times the electrical modulation frequency. At the same time, the triggering of the light pulses advantageously enables a particularly low-jitter behavior of the light pulses to be achieved, because, namely, a time-related variation of the light pulses is significantly reduced due to “locking-in of the optical light pulses”.

For the sizing of the optoelectronic component 200 as shown in FIGS. 2 and 3, it is seen as advantageous in one example if the width b of the optically active zone is about 2 μm. The total width B of the optoelectronic component 200 is then about 300 μm. At the same time, the lengths L1, L1′, L1″ and L1′″ of the absorber devices should not exceed a length of 100 μm in each case. The lengths L2, L2′, L2″ and L2′″ of the amplifier devices should each be approximately 200 μm. The lengths L3, L3′, L3″ and L3′″ of the further amplifier devices should not exceed a length of 300 μm.

In summary, in the case of the optoelectronic component as shown in FIGS. 2 and 3, a pulse generating device is monolithically integrated together with three auxiliary pulse generating devices in one single semiconductor substrate.

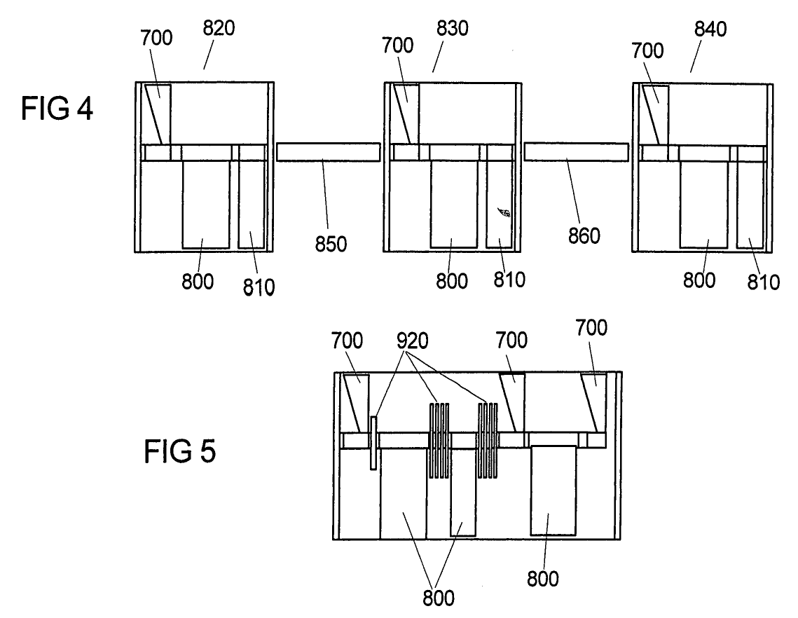

FIG. 4 shows a third exemplary embodiment of an optoelectronic component according to the invention in plan view. A pulse generating device 820 and two auxiliary pulse generating devices 830 and 840 can be seen.

The pulse generating device 820 can, for example, be a pulse generating device, which corresponds to the pulse generating device 190 as shown in FIG. 1 or the pulse generating device 210 as shown in FIG. 2. The two auxiliary pulse generating devices 830 and 840—in contrast to the exemplary embodiment as shown in FIGS. 2 and 3—are not integrated monolithically in the semiconductor substrate of the pulse generating device 820 but are separate from this. The optical connection between the two auxiliary pulse generating devices 830 and 840 or to the pulse generating device 820 is ensured by means of two passive waveguides 850 and 860, which can, for example, be plastic waveguides (e.g. BCB (benzocyclobutene) waveguides) or glass waveguides.

The passive waveguides 850, 860 and the three pulse generating devices 820, 830 and 840 can be applied on a sub-carrier, for example a silicon carrier or a glass carrier. The waveguides 850 and 860 can also be formed by (separate) glass fibers.

The connector pads 700 for the electrical connection of the absorber devices, the connector pads 800 for connecting the amplifier devices and the further connector pads 810 for the electrical connection of further amplifier devices are also shown in FIG. 4.

A plan view of a fourth exemplary embodiment of an optoelectronic component according to the invention is shown in FIG. 5. In FIG. 5, connector pads 700 for absorber devices and connector pads 800 for amplifier devices can be seen. Isolating devices 920, which isolate the amplifier devices from one another or from the absorber devices, can also be seen.

Although the invention has been illustrated and described with respect to one or more implementations, alterations and/or modifications may be made to the illustrated examples without departing from the spirit and scope of the appended claims. In addition, while a particular feature of the invention may have been disclosed with respect to only one of several implementations, such feature may be combined with one or more other features of the other implementations as may be desired and advantageous for any given or particular application. Furthermore, to the extent that the terms “including”, “includes”, “having”, “has”, “with”, or variants thereof are used in either the detailed description and the claims, such terms are intended to be inclusive in a manner similar to the term “comprising”.

List of reference symbols

| | |
|---|---|
| 10 | Optoelectronic component |
| 20 | Semiconductor substrate |
| 30, 40 | Active layer |
| 45 | Intermediate layer |
| 50 | Cover layer |
| 60 | Contact layer |
| 70, 80, 90 | Contacts |
| 100 | Absorber device |
| 100′, 100′′, 100′′′ | Auxiliary absorber device |
| 110, 120 | Amplifier device |
| 110′, 110′′, 110′′′ | Auxiliary amplifier device |
| 130 | Silvered edge |
| 140 | Isolating device |
| 150 | Vertical layers |
| 160 | Light emission surface |
| 170 | Coating |
| 180 | Separating point |
| 190, 210 | Pulse generating device |
| 220 | Silvered edge |
| 300, 400, 500 | Auxiliary pulse generating device |
| 310 | Separating point |
| 410 | Separating point |
| 510 | Separating point |
| 600 | Weakly reflective layer |
| 700 | Electrical connector pads |
| 800 | Connector pads |
| 810 | Further connector pads |
| 820 | Pulse generating device |
| 830, 840 | Auxiliary pulse generating device |
| 850, 860 | Waveguide |
| 920 | Isolating devices |

What is claimed is:

1. An optoelectronic component, comprising:
a semiconductor substrate;
an active layer overlying the semiconductor substrate;
a further active layer overlying the semiconductor substrate;
an absorber device associated with the further active layer;
an amplifier device associated with the active layer,
wherein the absorber device and the amplifier device reside within an optical resonator portion of the component.

2. The optoelectronic component of claim 1, wherein the optical resonator portion comprises a resonator wall defined by a silvered edge of the component.

3. The optoelectronic component of claim 2, wherein the absorber device borders directly against the silvered edge of the component.

4. The optoelectronic component of claim 1, wherein at least one of the active layer and the further active layer comprises quantum dot (QD) or a multiple quantum dot (MQD) layer.

5. The optoelectronic component of claim 1, wherein the active layer associated with the amplifier device comprises a QD layer or an MQD layer.

6. The optoelectronic component of claim 2, the component further comprising a light emission surface opposing the silvered edge, wherein the light emission surface comprises a reflecting layer having a reflection that is less than a reflection of the silvered edge.

7. The optoelectronic component of claim 1, further comprising a further amplifier device arranged next to the amplifier device on a side facing away from the absorber device.

8. The optoelectronic component of claim 7, further comprising a Bragg grating isolating device arranged between the amplifier device and the further amplifier device.

9. The optoelectronic component of claim 8, wherein the Bragg grating isolating device extends into the active layer and the further active layer.

10. The optoelectronic component of claim 6, wherein the amplifier device and absorber device together comprise a pulse generating device, further comprising at least one auxiliary pulse generating device comprising an auxiliary amplifier device and an auxiliary absorber device disposed between the pulse generating device and the light emission surface.

11. The optoelectronic component of claim 10, further comprising at least one isolating element disposed between the pulse generating device and the at least one auxiliary pulse generating device, respectively.

12. The optoelectronic component of claim 11, further comprising a cover layer overlying the further active layer, wherein the at least one isolating element comprises a recess, a trench formed by ion implantation or by a grating structure extending down vertically into the cover layer.

13. The optoelectronic component of claim 1, further comprising an electrical connector pad for the absorber device overlying a top portion of the component, wherein the electrical connector pad is tapered.

14. The optoelectronic component of claim 13, wherein a blocking voltage is applied to the electrical connector pad of the absorber device.

15. A method for generating light pulses in the optoelectrical component of claim 1, comprising:
applying a blocking voltage to the absorber device; and
modulating the applied blocking voltage.

16. The method of claim 15, wherein modulating the applied blocking voltage comprises modulating a frequency of the blocking voltage such that a pulse repetition rate of the generated light pulses is an integer multiple of the modulation frequency.

17. The method of claim 16, wherein the integer multiple is less than 100.

18. The method of claim 17, wherein the integer multiple is less than 11.

19. An optoelectronic component, comprising:
a semiconductor substrate;
an active layer overlying the semiconductor substrate;
a further active layer overlying the semiconductor substrate;
an absorber device associated with the further active layer;
an amplifier device associated with the active layer,
wherein the absorber device and the amplifier device reside within an optical resonator portion of the component, and
wherein a band gap of the active layer is optimized for operation of the amplifier device, and a band gap of the further active layer is optimized for operation of the absorber device.

20. The optoelectronic component of claim 19, wherein the band gaps of the active layer and the further active layer are selected to establish a dependency of a gain on a carrier density of the amplifier device to be substantially smaller than a dependency of an absorption on a carrier density of the absorber device.

21. The optoelectronic component of claim 19, wherein a band gap of the active layer and a band gap of the further active layer fulfill the conditions:
Et (further active layer)=hv, and
Et (active layer)−Et (further active layer)≦30 meV,
wherein Et is the band gap, h is Planck's constant, v is an optical frequency of the generated light pulses.
